(19) United States
(12) Patent Application Publication
(10) Pub. No.: US 2019/0232438 A1
(43) Pub. Date: Aug. 1, 2019

(54) SOLDER PASTE AND MOUNT STRUCTURE

(71) Applicant: Panasonic Intellectual Property Management Co., Ltd., Osaka (JP)

(72) Inventors: HIROHISA HINO, Osaka (JP); NAOMICHI OHASHI, Hyogo (JP); YASUHIRO SUZUKI, Osaka (JP); KOSO MATSUNO, Osaka (JP)

(21) Appl. No.: 16/223,952

(22) Filed: Dec. 18, 2018

(30) Foreign Application Priority Data
Jan. 31, 2018 (JP) 2018-015340

(51) Int. Cl. B23K 35/362; B23K 35/02; B23K 35/26; C22C 13/02; H05K 1/18; H01L 23/00; H05K 3/34

(52) U.S. Cl. CPC B23K 35/362; B23K 35/025; B23K 35/262; C22C 13/02; H05K 1/181; B23K 2101/40; H01L 24/81; H05K 3/3436; H05K 3/3457; H05K 3/3494; H01L 24/16

(57) ABSTRACT

Provided herein is a solder paste having low viscosity and easy coatability, and that provides high reinforcement for electronic components while satisfying both high room-temperature adhesion and high repairability, and forming a cured product of excellent properties, for example, high insulation against humidity. Amount structure including an electronic component mounted with the solder paste is also provided. The solder paste contains a solder powder and a flux. The flux contains an epoxy resin, a reactive diluent, a curing agent, an organic acid, and a rubber modified epoxy resin. The reactive diluent contains a compound having two or more epoxy groups, and has a viscosity of 150 mPa·s or more and 700 mPa·s or less. The reactive diluent has a total chlorine content of 0.5 weight % or less, and is contained in a proportion of 5 weight % or more and 45 weight % or less with respect to a total weight of the flux.

### TECHNICAL FIELD

The technical field relates mainly to solder pastes used for soldering of semiconductor components, electronic components, and the like to a circuit board, particularly a solder paste that contains an epoxy resin as its flux component. The technical field also relates to a mount structure.

### BACKGROUND

Mobile devices such as cell phones and PDAs (Personal Digital Assistants) have become smaller and more functional. A variety of mount structures such as BGA (Ball Grid Array), and CSP (Chip Scale Package) are available as a mount technology for accommodating such advancements. Mobile devices are often subjected to a mechanical load such as dropping impact. AQFP (Quad Flat Package) absorbs impact at its lead portion. BGA and CSP do not have leads that relieve impact, and it is important to provide reliability against impact in these structures.

A Pb eutectic solder, a common solder, has a melting point of 183° C. In contrast, a Sn-Ag-Cu-base solder, a typical example of modern lead-free solders, has a melting point, for example, about 30° C. higher than the melting point of the Pb eutectic solder, and the profile temperature of a reflow furnace reaches a temperature as high as 220 to 260° C. For mounting of components of weak high-temperature resistance on a circuit board, such components are usually separately bonded in a separate step by spot soldering. This has posed a serious drawback in productivity.

This has led to the use of low-melting-point Pb-free solders, for example, Sn-Zn-, Sn-Ag-In-, and Sn-Bi-base solders, which do not have the demerit of the Sn—Ag—Cu-base solder (hereinafter, referred to as “SAC solder”), specifically, a high melting point. However, a BGA connection using Sn-Zn-, Sn-Ag-In-, and Sn-Bi-base solders has not been fully established with regard to the connection reliability of the solder joint, particularly, reliability against impact.

This issue is addressed in related art. For example, Japanese Patent No. 5204241 proposes a semiconductor mount structure using a solder paste that contains a thermosetting resin in the flux (hereinafter, also referred to simply as “solder paste”) to improve reliability against impact at a joint, and a method for producing such a semiconductor mount structure.

An example of a composition of such a solder paste is a paste composition containing a solder powder, and a flux composed of an epoxy resin, a curing agent, an organic acid, and a thickener.

FIG. 5 is a cross sectional view of a CSP ball portion bonded with the solder paste of the related art. As shown in FIG. 5, the ball portion has a structure in which an electrode 22 provided on a circuit board 21, and an electrode 24 provided on a circuit board 23 are bonded to each other with a SAC solder bump 25 and a SnBi low-temperature solder conductive portion 29, and the periphery of the bonded portion is reinforced by a reinforcing portion 26b, which is a cured solid epoxy resin.

FIGS. 6A to 6C are cross sectional explanatory diagrams schematically representing the steps of bonding a ball portion of a CSP with the solder paste of the related art. The electrode 22 provided on the circuit board 21, and the electrode 24 provided on the circuit board 23 are bonded to each other with the SAC solder bump 25 and a traditional solder paste 27 containing a SnBi low-temperature solder, and these are heat cured with a drier 28 to complete the bond. The bond is reinforced by the reinforcing portion 26b, which is a cured solid epoxy resin surrounding the SnBi low-temperature solder conductive portion 29.

The solder paste containing the thermosetting resin forms the reinforcing structure as the resin separates from the solder being heated and melted in a bonding step, and covers the periphery of the solder. The reinforced solder joint has increased strength, and the reliability against impact can improve.

In mounting using the solder paste, the solder paste is heated with a reflow furnace after wire electrodes and the like are printed on predetermined positions of a circuit board using a metal mask. In heating of the solder paste, the flux acts to chemically remove the oxide film on the metal surface to be soldered, and the surface oxide film of the solder powder in a reduction reaction (activity known as “fluxing effect”), enabling joining by the molten solder. As the epoxy resin continuously cures, the wire electrodes of the circuit boards are bonded to parts while the resin provides reinforcement, all in a single heat reflow process.

### SUMMARY

Typically, a cream solder paste fails to provide stable conductivity unless it contains about 50 volume % of solder. However, a cream solder paste becomes very viscous when it has such a high solder powder content. To avoid this, a high-boiling-point solvent is added to a cream solder paste so that the paste has an adjusted low viscosity.

On the other hand, a solder paste containing a thermosetting resin in the flux is typically solvent free, and uses a bisphenol-base liquid epoxy resin to achieve a paste form, as described in Japanese Patent No. 5373464. However, the viscosity of the solder paste increases when it contains a large proportion of solder powder, and it becomes very difficult to handle the solder paste. It is not desirable to add a solvent as in a cream solder paste because the solvent, which is unreactive, interferes with the curing reaction of the epoxy resin and a curing agent, and functions as a plasticizer.

In a proposed method of achieving a low viscosity in a solder paste, solders of different particles sizes are closely packed as described in Japanese Patent No. 5728636.

As an example, a common epoxy adhesive uses a reactive diluent, specifically, a low-molecular-weight epoxy, instead of a solvent, to achieve a low viscosity. Typical examples of the reactive diluent include alkyl glycidyl ethers, such as butyl glycidyl ether, and 2-ethylhexyl glycidyl ether. Because these reactive diluents have very low viscosities, a solder paste using such a reactive diluent can have a greatly reduced viscosity. However, the reactive diluent is highly volatile because of its low boiling point, and vaporizes under the heat of curing. Another problem is that the reactive diluent, because it is monofunctional, tends to maintain low crosslink density, and the cured product often lacks rigidity, and the moisture absorption rate is high. Many of common reactive diluents also contain large numbers of impurity ions such as halogen ions, particularly chlorine ions, and, with the high moisture absorption rate, impair the insulation of a solder-bonded semiconductor component under humidity.

The solder pastes of the foregoing Japanese patents contain a rubber modified epoxy resin in the flux component of the solder paste to prevent defects due to dropping of amounted semiconductor at room temperature, and to improve repairability (remountability) at high temperature. However, the rubber modified epoxy resins contained in these solder pastes were found to have poor compatibility with the common epoxy. Specifically, in a solder paste using the epoxy, a bleed tends to occur in a surface of a cured product, and this causes problems such as adhesion of foreign materials. There accordingly is a need for a solder paste that does not cause bleeding even when it contains a rubber modified epoxy resin in the flux component.

The present disclosure is intended to provide a solution to the foregoing problems, and it is an object of the present disclosure to provide a solder paste having low viscosity and easy coatability, and that provides high reinforcement for electronic components while satisfying both high room-temperature adhesion and high repairability, and forming a cured product of excellent properties, for example, high insulation against humidity. The disclosure is also intended to provide amount structure including an electronic component mounted with such a solder paste.

A solder paste of an aspect of the present disclosure contains a solder powder and a flux. The flux contains an epoxy resin, a reactive diluent, a curing agent, an organic acid, and a rubber modified epoxy resin. The reactive diluent contains a compound having two or more epoxy groups, and has a viscosity of 150 mPa·s or more and 700 mPa·s or less. The reactive diluent has a total chlorine content of 0.5 weight % or less, and is contained in a proportion of 5 weight % or more and 45 weight % or less with respect to a total weight of the flux.

A mount structure of an aspect of the present disclosure is a mount structure in which an electronic component is mounted on a circuit board with the solder paste, the mount structure including a conductive portion where the electronic component and the circuit board are metallurgically bonded to each other, and a reinforcing portion formed by a cured product of the flux covering a periphery of the conductive portion.

The solder paste of the aspect of the present disclosure has low viscosity and easy coatability, and provides high reinforcement for electronic components while satisfying both high room-temperature adhesion and high repairability, and forming a cured product of excellent properties, for example, high insulation against humidity.

Specifically, in a mount structure of an electronic component mounted with the solder paste of the aspect of the present disclosure, the electronic component is bonded to a circuit board with a low-temperature solder, and the resin covers the periphery of the bonded portion. That is, the conductive portion formed by the solder is covered by a cured product of the flux, and a reinforced structure (reinforcing portion) is formed. The solder paste of the aspect of the present disclosure forming such a structure contains a selected reactive diluent of desirable properties that does not easily cause a decrease of crosslink density, and the solder paste has stable printability even though it is a low-viscosity paste with a high solder content. The mount structure after reflow has excellent insulation against humidity while satisfying both high room-temperature adhesion, and repairability under heat. The solder paste also can be prevented from causing bleeding, even though the flux component contains a rubber modified epoxy resin.

### BRIEF DESCRIPTION OF THE DRAWINGS

FIG. 1 is a cross sectional view of a CSP ball portion bonded with a solder paste of an embodiment of the present disclosure.

FIG. 2A is a cross sectional explanatory diagram schematically representing a process for connecting a ball portion of a CSP with the solder paste of the embodiment of the present disclosure.

FIG. 2B is a cross sectional explanatory diagram schematically representing a process for connecting a ball portion of a CSP with the solder paste of the embodiment of the present disclosure.

FIG. 2C is a cross sectional explanatory diagram schematically representing a process for connecting a ball portion of a CSP with the solder paste of the embodiment of the present disclosure.

FIG. 3A is a cross sectional explanatory diagram schematically representing a process for connecting a chip component with the solder paste of the embodiment of the present disclosure.

FIG. 3B is a cross sectional explanatory diagram schematically representing a process for connecting a chip component with the solder paste of the embodiment of the present disclosure.

FIG. 3C is a cross sectional explanatory diagram schematically representing a process for connecting a chip component with the solder paste of the embodiment of the present disclosure.

FIG. 4 is a cross sectional view schematically representing a method used to measure shear adhesion of a chip component.

FIG. 5 is a cross sectional view of a CSP ball portion bonded with a traditional solder paste.

FIG. 6A is a cross sectional explanatory diagram schematically representing a process of bonding a ball portion of a CSP with a traditional solder paste.

FIG. 6B is a cross sectional explanatory diagram schematically representing a process of bonding a ball portion of a CSP with a traditional solder paste.

FIG. 6C is a cross sectional explanatory diagram schematically representing a process of bonding a ball portion of a CSP with a traditional solder paste.

### DESCRIPTION OF EMBODIMENTS

An embodiment of the present disclosure is described below, with reference to the accompanying drawings.

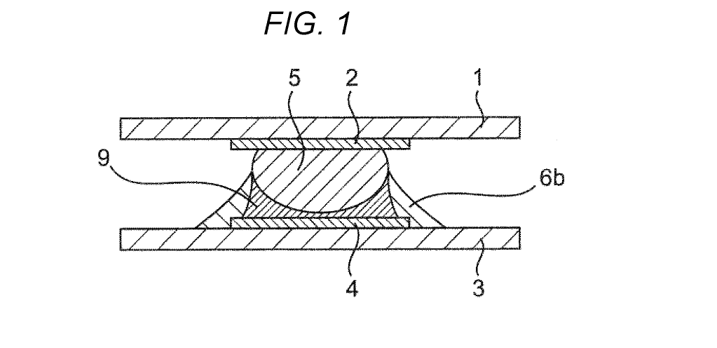

A solder paste of an embodiment of the present disclosure contains a solder powder and a flux. FIG. 1 is a cross sectional view of a CSP ball portion bonded with the solder paste of the embodiment of the present disclosure. As illustrated in FIG. 1, the ball portion has a structure in which an electrode 2 provided on a circuit board 1, and an electrode 4 provided on a circuit board 3 are metallurgically bonded to each other with a solder bump 5 and a solder powder-derived conductive portion 9, and the periphery of the bonded portion is reinforced by a reinforcing portion 6b, which is a flux-derived, cured solid epoxy resin.

The solder paste of the embodiment of the present disclosure is described below in detail with regard to its composition.

The solder paste of the embodiment of the present disclosure containing a solder powder and a flux may additionally contain other components, as required. The flux contains an epoxy resin, a reactive diluent, a curing agent, an organic acid (activating agent), and a rubber modified epoxy resin.

### Flux

The flux in the solder paste of the embodiment of the present disclosure contains an epoxy resin, a reactive diluent, a curing agent, an organic acid (activating agent), and a rubber modified epoxy resin. The flux content with respect to the total weight of the solder paste is preferably 10 weight % to 40 weight %, more preferably 15 weight % to 25 weight %, further preferably 18 weight % to 22 weight %. With the flux content falling in these ranges in the solder paste of the embodiment of the present disclosure, the solder paste can effectively achieve high connection reliability at the joint, excellent paste printability, and stable conductivity. The following more specifically describes the essential components of the flux.

### Epoxy Resin

The epoxy resin typically refers to a thermosetting resin that has an epoxy group within its structure, and that can be cured by heat. In the embodiment of the present disclosure, the epoxy resin (base epoxy resin) contained in the flux is an epoxy resin that is liquid at ordinary temperature. By using such an epoxy resin, other components, including solder particles, can be dispersed with ease. As used herein, “liquid at ordinary temperature” means that there is fluidity in a temperature range of 5° C. to 28° C., particularly at a room temperature of about 20° C. under the atmospheric pressure. The epoxy resin that is liquid at ordinary temperature is not particularly limited in terms of a molecular weight and a molecular structure, and various epoxy resins may be used, provided that the epoxy resin has two or more epoxy groups within the molecule. Examples of such epoxy resins include various liquid epoxy resins, including glycidyl ether, glycidyl amine, glycidyl ester, and olefin oxidized (alicyclic) liquid epoxy resins. Specific examples include bisphenol epoxy resins, such as bisphenol A epoxy resins, and bisphenol F epoxy resins; hydrogenated bisphenol epoxy resins, such as hydrogenated bisphenol A epoxy resins, and hydrogenated bisphenol F epoxy resins; biphenyl epoxy resins, naphthalene ring-containing epoxy resins, alicyclic epoxy resins, dicyclopentadiene epoxy resins, phenol novolac epoxy resins, cresol novolac epoxy resins, triphenylmethane epoxy resins, aliphatic epoxy resins, and triglycidyl isocyanurate. These may be used either alone or in a combination of two or more. In terms of reducing the viscosity of the liquid epoxy resin composition for sealing of semiconductors, and improving the quality of the cured product, preferred as the epoxy resin that is liquid at ordinary temperature are bisphenol epoxy resins, and hydrogenated bisphenol epoxy resins. An epoxy resin that is solid at ordinary temperature maybe used in combination. Examples of such epoxy resins that are solid at ordinary temperature include biphenyl epoxy resins, dicyclopentadiene epoxy resins, and triazine skeleton epoxy resins. The epoxy resin is used in a range of preferably 25 weight % to 90 weight %, more preferably 35 weight % to 70 weight %, further preferably 38 weight % to 63 weight % with respect to the total flux weight. With the epoxy resin content falling in these ranges in the flux of the embodiment of the present disclosure, the connection reliability of the joint can effectively improve.

### Reactive Diluent

The reactive diluent contained in the flux in the embodiment of the present disclosure contains a compound having two or more epoxy groups at the terminals or on side chains. Specifically, the reactive diluent is essentially of a compound that has two or more epoxy groups. As used herein, “essentially” in the context of reactive diluent means that the reactive diluent contains a compound having two or more epoxy groups in a proportion of preferably 90 weight % or more and less than 100 weight %, more preferably 95 weight % or more and less than 100 weight %, further preferably 99 weight % or more and less than 100 weight %, even more preferably 99.5 weight % or more and less than 100 weight % with respect to the total weight of the reactive diluent. The remainder includes impurities, for example, halogen ions (described later), that become included in manufacture, such as in the process of producing the reactive diluent. The reactive diluent has a viscosity of 150 mPa·s to 700 mPa·s, and contains chlorine in a total content of 0.5 weight % or less. From the standpoint of primarily the physical properties of a cured product of the flux, the reactive diluent is preferably one configured substantially from a compound having a backbone with a rigid skeleton, for example, such as a benzene ring, and a cyclopentadiene skeleton.

The reactive diluent requires two or more epoxy groups because the reactive diluent fails to have high crosslink density through reaction with the curing agent when the compound has only one epoxy group. However, the reactive diluent increases its viscosity as the number of epoxy groups increases from two. The viscosity reducing effect is small in such a reactive diluent, and the reactive diluent increases the viscosity of the solder paste containing it. This results in poor coatability. After intensive investigations of the balance between crosslink density and viscosity, the present inventors found that the reactive diluent can have the most desirable properties when it is essentially of a compound that has two or three epoxy groups, and when the reactive diluent has a viscosity of 150 mPa·s to 700 mPa·s. A reactive diluent having a viscosity of less than 150 mPa·s did not have a rigid skeleton, or the epoxys were primarily monofunctional, though the viscosity reducing effect was high. A reactive diluent having a viscosity of more than 700 mPa·s had a very rigid skeleton, and the epoxys were primarily multifunctional. Though the physical properties were desirable, the viscosity reducing effect was weak. The reactive diluent used in the present disclosure accordingly has a viscosity of more preferably 170 mPa·s to 680 mPa·s, further preferably 200 mPa·s to 660 mPa·s, even more preferably 230 mPa·s to 650 mPa·s. Here, the viscosity of the reactive diluent is a value measured with a viscometer E manufactured by Toki Sangyo Co., Ltd.

For reasons related to manufacture, a reactive diluent typically contains large amounts of chlorine ions. Halogen ions, such as chlorine ions, cause an increase of leak current in electric and electronic components. The chlorine in a reactive diluent ionizes in response to entry of moisture, and causes leak defects and corrosion in electric and electronic components. Against these problems, it is important to reduce the amount of chlorine ions in the reactive diluent. After intensive investigations, the present inventors found that desirable insulation against humidity can be obtained when the total chlorine content in the reactive diluent is 0.5 weight % or less. The total chlorine content is preferably 0.4 weight % or less, further preferably 0.3 weight % or less, even more preferably 0.2 weight % or less, further preferably 0.1 weight % or less, more preferably 0.08 weight % or less. Here, the total chlorine content in the reactive diluent (or the amount of chlorine ions in the reactive diluent) is an amount obtained after the conversion of a measured value by a potentiometric titrator AT-710 (Kyoto Electronics Manufacturing Co., Ltd.) with a silver nitrate standard solution. Insulation after moisture resistance treatment decreases when the total chlorine content in the reactive diluent is more than 0.5 weight %.

Considering these, the reactive diluent compound used in the present disclosure is preferably dicyclopentadiene dimethanol diglycidyl ether, 1,3-bis[(2,3-epoxypropyl)oxy]benzene, or N,N-bis(2,3-epoxypropyl)-4-(2,3-epoxypropoxy)aniline. In other words, the reactive diluent contains at least one compound selected from the group consisting of dicyclopentadiene dimethanol diglycidyl ether, 1,3-bis[(2,3-epoxypropyl)oxy]benzene, and N,N-bis(2,3-epoxypropyl)-4-(2,3-epoxypropoxy)aniline.

Considering the fluidity of the solder paste, and reduction of crosslink density, the reactive diluent is contained in a proportion of 5 weight % to 45 weight % with respect to the total flux weight. The proportion of the reactive diluent is preferably 5 weight % to 40 weight %, further preferably 5 weight % to 35 weight %.

Dicyclopentadiene dimethanol diglycidyl ether (represented by the structural formula in chemical formula 1 below) has a structure with two epoxy groups attached to either terminal of dicyclopentadiene, a compound having a rigid skeleton. As an example, the properties of a reactive diluent of essentially dicyclopentadiene dimethanol diglycidyl ether were measured with ADEKA EP-4088L. The viscosity was 230 mPa·s, and the total chlorine content was 0.04 weight %. Because dicyclopentadiene dimethanol diglycidyl ether has a rigid skeleton, an epoxy cured product using a reactive diluent of dicyclopentadiene dimethanol diglycidyl ether should have strong room-temperature adhesion.

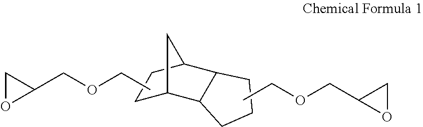

1,3-Bis[(2,3-epoxypropyl)oxy]benzene (represented by the structural formula in chemical formula 2 below) has a structure with two epoxy groups at either terminal of the stable benzene ring skeleton. As an example, the properties of a reactive diluent of essentially 1,3-bis[(2,3-epoxypropyl)oxy]benzene were measured with EX-2011M available from Nagase ChemteX Corporation. The viscosity was 400 mPa·s, and the total chlorine content was 0.04 weight %. Because 1,3-bis[(2,3-epoxypropyl)oxy]benzene has a rigid benzene ring, an epoxy cured product using a reactive diluent of 1,3-bis[(2,3-epoxypropyl)oxy]benzene should have strong room-temperature adhesion, and low moisture absorption.

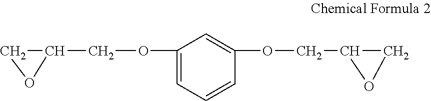 [SMILES: c1cc(OCC2CO2)cc(OCC2CO2)c1]

N,N-Bis(2,3-epoxypropyl)-4-(2,3-epoxypropoxy)aniline (represented by the structural formula in chemical formula 3 below) has a structure with two epoxy groups attached to the nitrogen atom of the stable aniline structure skeleton, and one epoxy group attached to the benzene skeleton. As an example, the properties of a reactive diluent of essentially N,N-bis(2,3-epoxypropyl)-4-(2,3-epoxypropoxy) aniline were measured with ADEKA EP-3950S. The viscosity was 650 mPa·s, and the total chlorine content was 0.08 weight %. Because N,N-bis(2,3-epoxypropyl)-4-(2,3-epoxypropoxy)aniline has a rigid benzene ring, and a highly polar nitrogen atom, an epoxy cured product using a reactive diluent of N,N-bis(2,3-epoxypropyl)-4-(2,3-epoxypropoxy)aniline should have strong room-temperature adhesion.

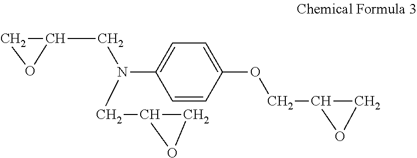 [SMILES: c1cc(N(CC2CO2)CC2CO2)ccc1OCC1CO1]

### Curing Agent

The curing agent may be a common epoxy resin curing agent, for example, such as acid anhydrides, phenol novolac, various thiol compounds, various amines, dicyandiamide, imidazoles, metal complexes, and adduct compounds thereof, for example, such as an adduct modified product of polyamine. However, the curing agent is not limited to these. Particularly preferred for use are imidazoles, which satisfy both single-component properties and solder meltability. Non-limiting examples of imidazoles include 2MZ, C11Z, 2PZ, 2E4MZ, 2P4MZ, 1B2MZ, 1B2PZ, 2MZ-CN, 2E4MZ-CN, 2PZ-CN, C11Z-CN, 2PZ-CNS, C11Z-CNS, 2MZ-A, C11Z-A, 2E4MZ-A, 2P4MHZ, 2PHZ, 2MA-OK, 2PZ-OK (available from Shikoku Chemicals Corporation under these trade names), and compounds obtained after adding these imidazoles to an epoxy resin. The curing agent may be used in the form of a microcapsule by being coated with a polymer material such as a polyurethane or polyester polymer material.

The curing agent is used in an appropriately adjusted amount. Preferably, the amount is adjusted so that the stoichiometric equivalent ratio of the curing agent with respect to the epoxy equivalent of the epoxy resin ranges from 0.8 to 1.2. With the curing agent content falling in this range, the connection reliability and the high-temperature repairability of the components at the joint can effectively improve.

A curing promoting agent may be mixed into the flux, as required. Aside from imidazoles such as above, the curing promoting agent may be selected from: cyclic amines such as tertiary amines, 1,8-diazabicyclo(5.4.0)undecene-7, and 1,5-diazabicyclo(4.3.0)nonene-5, and tetraphenylborate salts thereof; trialkylphosphines such as tributylphosphine; triarylphosphines such as triphenylphosphine; quaternary phosphonium salts such as tetraphenyl phosphonium tetraphenyl borate, and tetra(n-butyl)phosphonium tetraphenyl borate; metal complexes such as Fe acetyl acetonate, and adduct compounds thereof. The content of the curing promoting agent is appropriately adjusted, taking into consideration factors such as gelation time, and storage stability.

### Organic Acid

The organic acid (activating agent) is not particularly limited, and acids of any organic compounds may be used. Examples of the organic acid include resin component materials such as abietic acid; various amines and salts thereof; sebacic acid, adipic acid, glutaric acid, succinic acid, malonic acid, citric acid, and pimelic acid. The organic acid has a desirable fluxing effect (as used herein, “fluxing effect” means the reducing effect that removes the oxide coating that has occurred on the metal surface to which the solder paste is applied, and the effect that lowers the surface tension of a molten solder to promote solder wettability for the soldered metal surface).

These organic acids may be used as a single component, or as a mixture of two or more components. Preferred among these organic acids are adipic acid and glutaric acid because these have a high fluxing effect, and are stable as compounds. The organic acid is used in an appropriately adjusted amount, and is used preferably in a stoicheiometric equivalent ratio of 0.8 to 1.2 with respect to an epoxy equivalent of the epoxy resin. With the organic acid content falling in this range, the connection reliability and the high-temperature repairability of the components at the joint can effectively improve.

### Rubber Modified Epoxy Resin

The flux in the solder paste of the embodiment of the present disclosure contains a rubber modified epoxy resin. For advantages such as strong adhesion and insulation, epoxy resins are typically used in a range of applications including adhesives, coating materials, and electrical and electronic materials. The inherent drawback, however, is a lack of toughness. Because of rigidity, cracking and other defects tend to occur under a mechanical load. Specifically, the component becomes detached when a mechanical load is applied to its joint portion, and the reliable lifetime becomes shorter.

An epoxy resin can be rendered tenacious by, for example, polymer alloying of a flexible resin (forming an interpenetrating polymer network, or IPN, by adding a strong thermoplastic polymer, and thus forming an admixture of different polymers), or by forming an island-in-sea structure, or introducing various rubber skeletons.

Possible examples of such methods include forming a polymer alloy of epoxy resin and acrylic resin, and forming an island-in-sea structure of epoxy resin and silicone resin. These techniques involve providing a special, low-elastic characteristic by creating a localized micro state of different resins. However, stably creating such a disperse state is highly difficult.

It is accordingly preferable to make the epoxy resin tenacious by itself in the form of a rubber modified epoxy resin in which an epoxy group that provides crosslinkability is contained as a functional group in the epoxy resin skeleton, and that contains, for example, a silicone skeleton, a polybutadiene skeleton, and/or a polyurethane skeleton as a functional group that provides tenacity.

With regard to the problem involving the compatibility between volatile impurities and the epoxy resin (base epoxy resin) , an epoxy resin having a silicone skeleton within the molecule is not as convenient as epoxy resins having other skeletons. Specific examples of such silicone epoxy resins available in the market include X-22-163, X-22-343, X-22-2000 (all available from Shin-Etsu Silicone) , and TSF4730 (available from Momentive Performance Materials Inc.).

The rubber modified epoxy resin having a polybutadiene skeleton within the molecule has both the polybutadiene structure and an epoxy group within the molecule, and has both strong adhesion and strong tenacity. Two of the possible forms of the rubber modified epoxy resin having a polybutadiene skeleton within the molecule are one in which the polybutadiene skeleton occurs in the main chain (including 1,4-polybutadiene), and one in which the polybutadiene skeleton occurs in a side chain (including 1,2-polybutadiene). Either form can develop the characteristic tenacity of rubber, and can preferably be used. Polybutadiene, which is hydrogenated at the double bonds, also has similar rubber characteristics, and shows excellent heat resistance because the lack of double bonds makes the molecule hardly oxidizable.

The rubber modified epoxy resin is preferably liquid when an epoxy resin having a polybutadiene skeleton is used as a flux component. However, the rubber modified epoxy resin may be solid, provided that it liquefies when used with a liquid epoxy resin, or when a solvent is added. When the rubber modified epoxy resin having a polybutadiene skeleton within the molecule is incorporated in a cross-linked structure by reacting with a curing agent, the polybutadiene skeleton, which has a relatively hard structure at room temperature, shows rubber-like elasticity in a high-temperature environment (specifically, for example, 160° C.) because of the strong molecular motion at such a high temperature. This provides very low elasticity in the cured product. Thus, when used as the rubber modified epoxy resin, the epoxy resin having a polybutadiene skeleton within the molecule can provide a solder paste that strongly adheres to the base material at room temperature, and that has weak adhesion in a high-temperature environment. The solder paste can be removed with ease by physically applying a force using a spurtle or the like in a high-temperature environment.

An example of the rubber modified epoxy resin having a polybutadiene skeleton within the molecule is represented by the chemical formula 4 below. However, the structure is not limited to the structure represented by chemical formula 4, and any epoxy resin maybe used that has a polybutadiene skeleton and an epoxy group within the molecule. Specific examples include commercially available products such as Epolead PB3600, PB4700 (both are available from Diecel Corporation), Nisseki Polybutadiene E-1000-3.5 (Nippon Petrochemicals), and R-15EPT, R-45EPT (Nagase ChemteX Corporation).

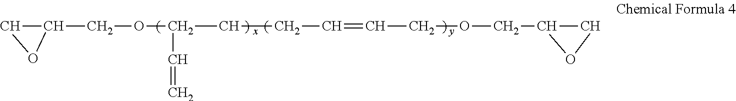

(X and Y represent an index of repeating structure.)

The epoxy resin having a polyurethane skeleton within the molecule has both the urethane structure and an epoxy group within the molecule, and can have both strong adhesion and strong tenacity. An example of the epoxy resin having a polyurethane skeleton within the molecule is represented by the chemical formula 5 below. However, the structure is not limited to the structure represented by chemical formula 5, and any epoxy resin may be used that has a polyurethane skeleton and an epoxy group within the molecule. The polyurethane skeleton is formed typically by a reaction between polyol and polyisocyanate, and an epoxy group is introduced later. However, the method of production is not particularly limited. The epoxy resin having a polyurethane skeleton within the molecule may have various structures (e.g., aliphatic skeleton) on other main chain skeletons, provided that the polyurethane skeleton and epoxy groups are present.

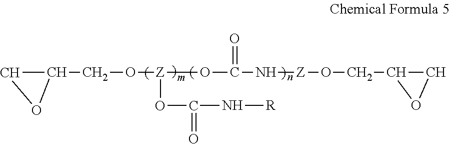

(m and n represent an index of repeating structure, and z represents an aliphatic skeleton.)

The rubber modified epoxy resin is preferably liquid when an epoxy resin having a polyurethane skeleton is used as a flux component. However, the rubber modified epoxy resin may be solid, provided that it liquefies when used with a liquid epoxy resin, or when a solvent is added. Once the rubber modified epoxy resin having a polyurethane skeleton within the molecule is incorporated in a cross-linked structure by reacting with the curing agent, the polyurethane skeleton, with its hard structure, shows high shear adhesion under room temperature. That is, with the tenacity of the polyurethane skeleton, the cross-linked structure does not easily crack even when a shear force is applied to the chip and other components at room temperature. This makes the solder paste not easily detachable. A cured product of the epoxy resin having a polyurethane skeleton can thus exhibit high release reliability against shear. Specific examples of the epoxy resin having a polyurethane skeleton within the molecule include commercially available products such as EPU-7N and EPU-73B (both available from ADEKA).

At a high temperature equal to or greater than the Tg of the flux, the adhesion strength of when a chip component is mounted and attached to a circuit board with the solder paste using the rubber modified epoxy resin having a polybutadiene skeleton as in the embodiment of the present disclosure is significantly weaker than when a solder paste that does not contain the rubber modified epoxy resin is used. That is, the chip component can be removed with ease by heating the joint to high temperature. Other desirable properties, including a balance between adhesion strength and printability, can be obtained when the epoxy resin having a polybutadiene skeleton is solely used as the rubber modified epoxy resin in the flux, and contained in a proportion of 2 weight % to 30 weight % of the total flux weight.

At room temperature, the adhesion strength of when a chip component is mounted and attached to a circuit board with the solder paste using the rubber modified epoxy resin having a polyurethane skeleton as in the embodiment of the present disclosure is higher than when a solder paste that does not contain the rubber modified epoxy resin is used. That is, the joint has high adhesion at room temperature. Other desirable properties, including a balance between adhesion strength and printability, can be obtained when the epoxy resin having a polyurethane skeleton is solely used as the rubber modified epoxy resin in the flux, and contained in a proportion of 1 weight % to 20 weight % of the total flux weight. The rubber modified epoxy resin having a polybutadiene skeleton, and the rubber modified epoxy resin having a polyurethane skeleton may be used together. That is, in the flux of the embodiment of the present disclosure, the rubber modified epoxy resin may include at least one selected from the group consisting of an epoxy resin having a polybutadiene skeleton, and an epoxy resin having a polyurethane skeleton.

The rubber modified epoxy resin having a polybutadiene skeleton, and/or the rubber modified epoxy resin having a polyurethane skeleton can develop desirable properties such as those described above. However, these epoxy resins have poor compatibility with common epoxys. Specifically, while these epoxy resins show tenacity with their polybutadiene skeleton and/or polyurethane skeleton, compatibility with common epoxys is poor because of high molecular weights. This causes an unreacted rubber modified epoxy resin to bleed on a surface of the epoxy cured product. It was found that this results in a tacky surface on the cured product, attracting dust and impairing the moisture absorption rate.

The present inventors found that such bleeding due to the rubber modified epoxy resin can be prevented by containing the reactive diluent in the flux of the embodiment of the present disclosure. After further studies, the present inventors also found that the preferred content of the reactive diluent is 5 weight % to 30 weight % of the total flux weight, as mentioned above. The bleed preventing effect becomes weaker when the content is less than 5 weight %. With a content of more than 30 weight %, the crosslink density decreases, and the moisture absorption rate increases, with the result that insulation against humidity deteriorates, as will be described later.

With the solder paste of the embodiment of the present disclosure, an electronic component such as a semiconductor component can be mounted on other components such as a circuit board having conductive wires. The mount structure has a joint connecting the terminal of the electronic component to the electrode of the circuit board. The joint has a reinforced structure (reinforcing portion) with the cured epoxy resin reinforcing the periphery of the solder (conductive portion). The epoxy resin cured in the periphery of the solder is insulating. However, when halogen ions such as chlorine ions are present in the cured product, a leak current occurs, and the insulation deteriorates in the cured epoxy resin portion when the cured product absorbs moisture under high humidity conditions. Possible factors involved in this phenomenon are the amount of the halogen ions, particularly chlorine ions, present in the cured product of epoxy resin, and moisture absorption rate and adhesion. Because the impact of these three factors is not readily quantifiable, the present inventors attempted to restrict the total chlorine content in the reactive diluent, and successfully maintained insulation. Specifically, the preferred total chlorine content in the reactive diluent was found to be 0.5 weight % or less, as mentioned above.

The flux in the solder paste of the embodiment of the present disclosure may contain other components, for example, such as common modifying agents and additives. For the purpose of reducing viscosity and imparting fluidity to the solder paste, a low-boiling-point solvent or a diluent may be added. It is also effective to add, for example, hydrogenated castor oil or stearamide as a thixotropy imparting agent for maintaining the printed shape.

### Solder Powder

The solder powder contained in the solder paste of the embodiment of the present disclosure is preferably a solder powder having a melting point of 240° C. or less. The lower limit of the melting point of the solder particle is not particularly limited, and is preferably 130° C. or more. The solder balls of a BGA or a CSP semiconductor use a tin-silver-copper (SAC) solder powder. Remelting of the SAC solder powder can be prevented when the solder powder used in the solder paste has a melting point lower than the melting point (220° C.) of the SAC solder powder. The composition of the solder powder is not particularly limited, and the solder powder may have a form of a solder alloy. For example, a Sn base alloy may be used. The solder powder may be preferably one that contains 22 weight % to 68 weight % of Bi, 0 weight % to 2 weight % of Ag, and 0 weight % to 73 weight % of In, and in which the balance is Sn. More preferably, for example, SnBi-base 42Sn-58Bi, 42Sn-57Bi-1.0Ag, and 16Sn-56Bi-28In may be used. The solder powder content with respect to the total mass of the solder paste of the embodiment of the present disclosure is preferably 50 weight % to 95 weight %, more preferably 60 weight % to 90 weight%, further preferably 75 weight % to 85 weight %. With the solder powder content of the solder paste of the embodiment of the present disclosure falling in these ranges, the paste can effectively accomplish high joint connection reliability and desirable printability at the same time.

In describing the composition of the solder powder in this specification, the symbols of the elements contained in the solder powder are linked by hyphens. In the metal composition of the solder powder described herein, the metallic elements are often preceded by numerical values or numerical ranges. These numerical values or numerical ranges represent the fraction of each element of the metal composition in mass % (=weight %), as commonly used in the art. The solder powder may contain trace amounts of incidental metals, for example, such as Ni, Zn, Sb, and Cu, provided that the solder powder is configured substantially from the elements shown.

In the specification, the melting point of the solder powder is the temperature after the solder powder has melted in an observation of state changes of a sample under the applied heat of increasing temperatures, and may be measured using, for example, DSC or TG-DTA.

The following describes a method for preparing the solder paste of the embodiment of the present disclosure, and a specific exemplary method for producing (or manufacturing) amount structure by mounting an electronic component on a circuit board using the solder paste.

First, the flux is produced by weighing and mixing the epoxy resin, the reactive diluent, the curing agent, the organic acid, and the rubber modified epoxy resin. The solder powder is then added to the flux, and mixed and kneaded.

A semiconductor component can be mounted on, for example, a circuit board having conductive wires, using the solder paste of the embodiment of the present disclosure. The mount structure of the embodiment of the present disclosure, for example, a semiconductor device, has a joint where the terminal of the semiconductor component and the electrode of the circuit board are bonded to each other with the solder paste. The solder paste can be applied as follows, for example. A metal mask having through holes corresponding in position to the electrodes is laid over the circuit board. The solder paste is then applied to the surface of the metal mask, and the through holes are filled with the solder paste using a squeegee. Removing the metal mask from the circuit board results in the solder paste being applied to each electrode on the circuit board.

While the solder paste is in an uncured state, a chip component or a semiconductor component is stacked on the circuit board with the terminal of the chip component or the semiconductor component facing the electrode of the circuit board, using a tool such as a chip mounter. Here, the chip component may be, for example, a chip resistor or a chip capacitor. The semiconductor component may be, for example, a CSP or BGA semiconductor package having a solder ball as the terminal, or a QFP semiconductor package provided with a lead terminal. The semiconductor component also may be a semiconductor device (bare chip) provided with a terminal without being housed in a package.

In this state, the printed wiring board with the chip component is heated to a predetermined heating temperature with a reflow furnace. The heating temperature is appropriately set to a temperature that sufficiently melts the solder powder, and at which the cure reaction of the resin component sufficiently proceeds. Preferably, the heating temperature is set so that the agglomeration and melting of the solder powder will not be inhibited by the progression of the cure reaction of the epoxy resin before the solder powder completely melts. The preferred heating temperature to this end is a temperature that is at least 10° C. higher than the melting point of the solder powder, and at most 60° C. higher than the melting point of the solder powder.

After these processes, a semiconductor device of an embodiment of the present disclosure is produced that has a joint where the terminal of the chip component or semiconductor component and the electrode of the circuit board are connected to each other via the solder paste of the embodiment of the present disclosure. The joint includes a solder joint (conductive portion) where the solder powder and the solder ball have melted and integrated, and a cured epoxy resin portion (reinforcing portion) where the cured product of the flux covers the periphery of the conductive portion. In this manner, the solder paste of the embodiment of the present disclosure can be used to produce amount structure in which a component and a substrate are electrically bonded to each other with the conductive portion, and the reinforcing portion provides mechanical reinforcement.

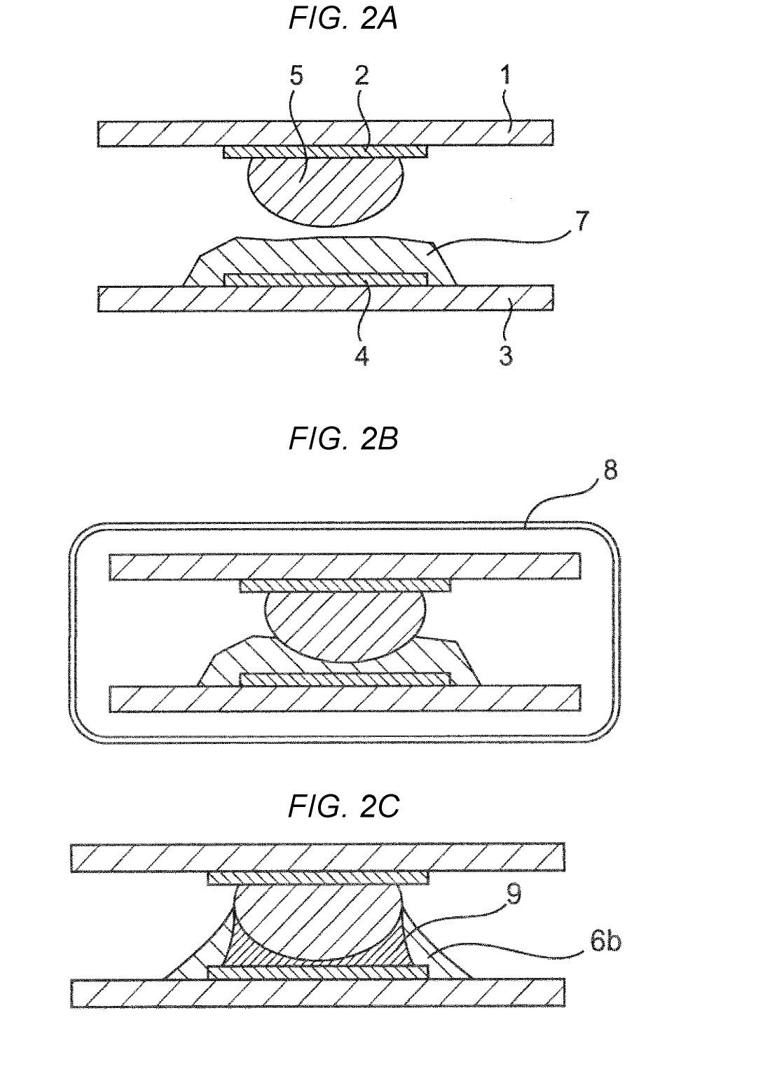

FIGS. 2A to 2C are cross sectional explanatory diagrams schematically representing processes for connecting a ball portion of a CSP with the solder paste of the embodiment of the present disclosure. As illustrated in FIGS. 2A to 2C, an electrode 2 provided on a circuit board 1, and an electrode 4 provided on a circuit board 3 are bonded to each other with a solder bump 5 and a solder paste 7, and the assembly is heat cured with a drier 8 to complete the bond. In the resulting structure, the periphery of the conductive portion 9 is reinforced by the reinforcing portion 6b a cured solid epoxy resin.

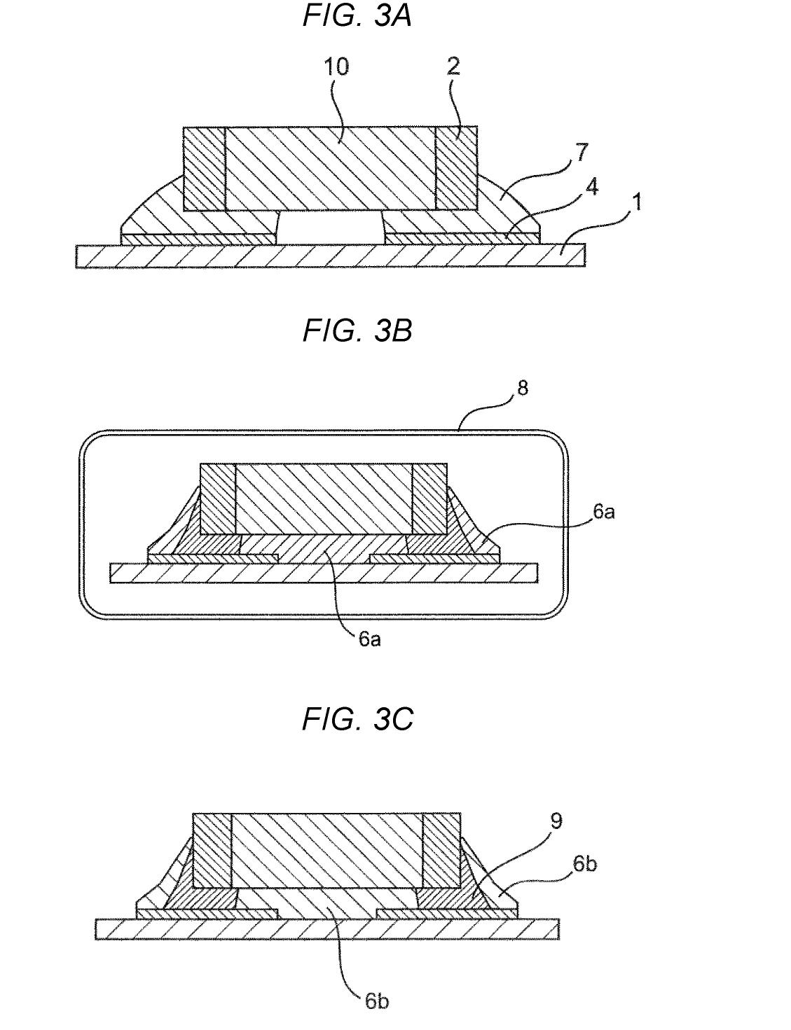

FIGS. 3A to 3C are cross sectional explanatory diagrams schematically representing processes for bonding a chip component with the solder paste of the embodiment of the present disclosure. As illustrated in FIGS. 3A to 3C, a chip component 10 is mounted on the solder paste 7 applied on an electrode 4 provided on the circuit board 1, and the assembly is heat cured with the drier 8. This causes the solder to melt, and form the conductive portion 9. The pressure of the agglomerated solder pushes out the liquid epoxy resin, and forms a structure in which the epoxy resin covers the periphery of the solder, and/or the bottom of the chip component 10. By subsequent heating, the epoxy resin cures into the reinforcing portion 6b, a solid epoxy resin. This completes the production of the mount structure having the reinforcing portion 6b and the conductive portion 9.

### EXAMPLES

The following describes Examples and Comparative Examples of the present disclosure. It is to be noted that the forms of the Examples and Comparative Examples of the present disclosure below are merely illustrative, and are not intended to limit the present disclosure in any ways. In the following Examples and Comparative Examples, “parts” and “%” are by weight, unless otherwise specifically stated.

### Production of Solder Paste

First, a base epoxy resin, a rubber modified epoxy resin, a reactive diluent, an organic acid, and a curing agent were weighed so that these components were contained in the solder paste in the weight parts shown in Table 1. These components were placed and kneaded in a planetary mixer, and uniformly dispersed in the epoxy resin to produce the fluxes of Examples 1 to 6 and Comparative Examples 1 to 4. The bisphenol-F epoxy resin jER806 available from Japan Epoxy Resin Co., Ltd. was used as the base epoxy resin. The polybutadiene-modified epoxy resin R-15EPT available from Nagase ChemteX Corporation, and the urethane-modified epoxy resin EPU-7N available from ADEKA were appropriately selected and used as the rubber modified epoxy resin. A glutaric acid from Kanto Kagaku was used as the organic acid. The imidazole-based curing agent 2P4MHZ (2-phenyl-4-methyl-5-hydroxymethylimidazole) available from Shikoku Chemicals Corporation was used as the curing agent.

The following reactive diluents were used in Examples 1 to 6, and in Comparative Examples 1, 3, and 4.

EP-4088L (dicyclopentadiene dimethanol diglycidyl ether) from ADEKA

EP-3950S (N,N-bis(2,3-epoxypropyl)-4-(2,3-epoxypropoxy)aniline) from ADEKA

EX-201IM (1,3-bis[(2,3-epoxypropyl)oxy]benzene) from Nagase ChemteX Corporation

DME 100 (1,4-cyclohexane dimethanol diglycidyl ether) from New Japan Chemical Co., Ltd.

ED-5095 (tert-butylphenyl glycidyl ether) from ADEKA

These reactive diluents were appropriately used as shown in Table 1. The reactive diluent was not used in Comparative Example 2.

The solder powder was added to the fluxes of Examples 1 to 6 and Comparative Examples 1 to 4 in the weight parts shown in Table 1, and the mixture was kneaded to prepare a solder paste. The solder powders used in Examples 1 to 5 and Comparative Examples 1 to 4 had the solder composition 42Sn-58Bi specified by JIS H42B:58A. The solder powder used in Example 6 had the solder composition 42Sn-57Bi-1.0Ag. The solder powders were produced according to an ordinary method. The solder particles had an average particle size of 15 μm, and a melting point of 139° C.

As used herein, “average particle size” is the particle size (D50) at a cumulative 50% point on a cumulative curve with respect to a total 100% volume in a volume-based particle size distribution. Average particle size can be measured using a laser-diffraction scattering particle-size and particle-distribution measurement device, or a scanning electron microscope.

### Production of Adhesion Evaluation Device

The solder paste produced in the manner described above was printed on an Au-plated electrode on a circuit board (FR-4 substrate) in a thickness of 0.1=to form a solder paste printed portion, using a metal mask.

A chip resistor (tin electrode) measuring 3.2 mm×1.6 mm in size was then mounted on the solder paste printed portion on the circuit board, using a chip mounter. The circuit board used copper as electrode material, and a glass epoxy material as substrate material. By using a reflow device, the assembly was heated at 160° C. for 6 minutes to form a joint, and produce an evaluation device.

### Evaluation

Examples 1 to 6, and Comparative Examples 1 to 4 were evaluated with respect to the following items. The evaluation results for each example and comparative example are presented in Table 1 as properties of the solder paste.

### Printability

The printability of the solder paste was evaluated by observing the shape of the solder paste printed with a metal mask. In the observation, the solder paste was visually checked for the extent of confinement in the electrode area, and dripping and pointing. The evaluation of printability is based on the transferred shape of the paste on the electrode of the circuit board through the through hole of the mask. The printability was “Good” when the shape was maintained in the electrode portion, “Acceptable” when the shape was partially disrupted (dripping or pointing, or both), and “Poor” when the shape was seriously disrupted.

### Room-Temperature Adhesion

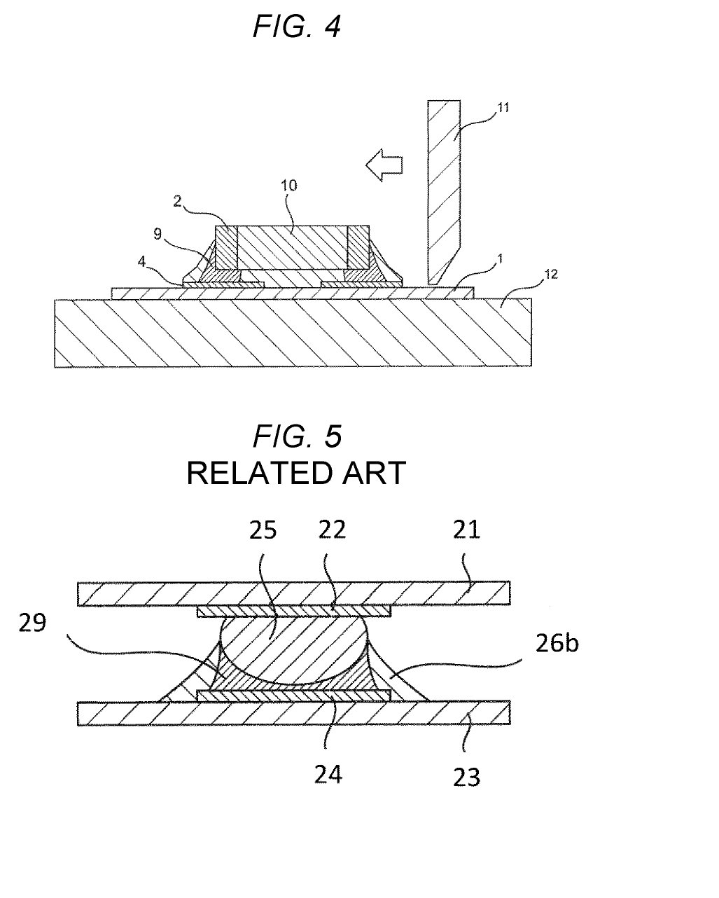

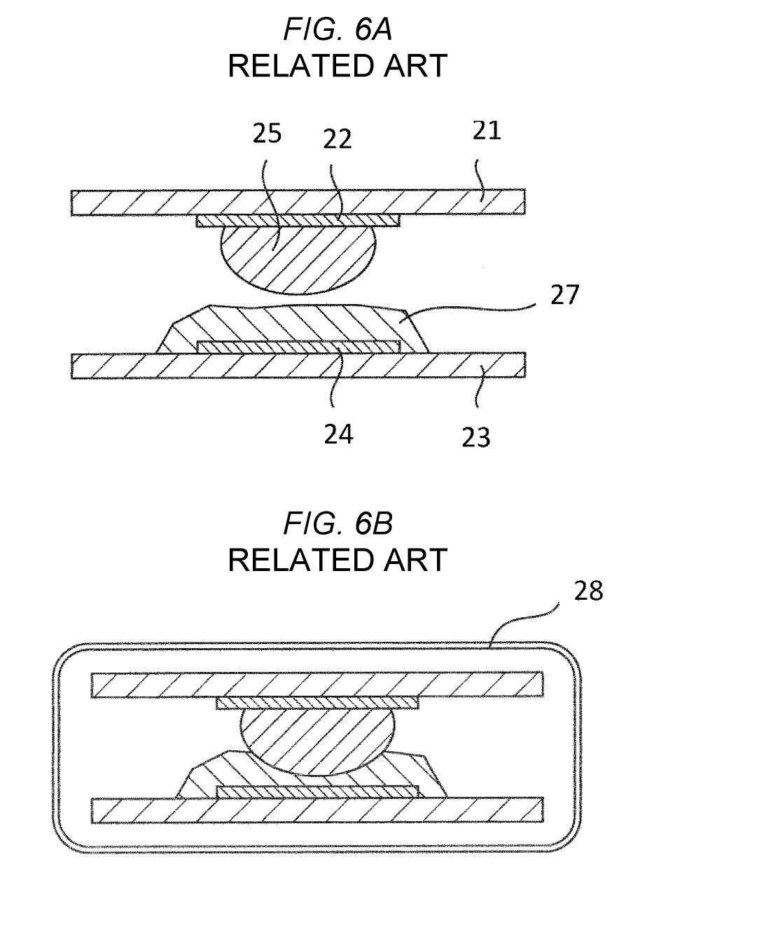

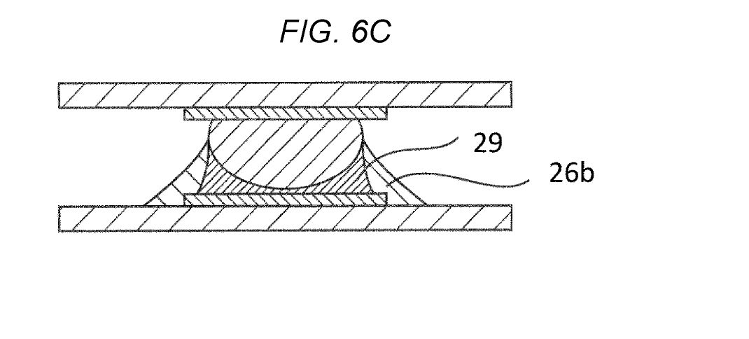

FIG. 4 is a schematic cross sectional view representing the method used to measure the shear adhesion of the chip component. The chip component 10 was fixed on a heatable hot plate stage 12, and horizontally pushed with a shear jig 11 to measure adhesion strength. The room-temperature adhesion of the solder paste was evaluated by measuring the shear adhesion of the adhesion evaluation device as above at room temperature (20° C.) using a Series 4000 bond tester available from DAGE. In the evaluation of room-temperature adhesion, the evaluation result is “Good” when the joint remained undamaged even under an applied load of more than 15 kg/chip, and “Poor” when the joint was damaged under an applied load of less than 14 kg/chip.

### High-Temperature Adhesion

The solder paste was also evaluated for high-temperature adhesion by measuring shear adhesion with the DAGE Series 4000 bond tester in the same manner as in the evaluation of room-temperature adhesion, except that the measurement was made after the evaluation device was heated to 160° C. through the hot plate with the evaluation device fixed on the hot plate stage 12 as shown in FIG. 4. In the evaluation of high-temperature adhesion, the evaluation result is “Good” when the joint was removable under an applied load of 5 kg/chip or less, “Acceptable” when the joint was removable under an applied load of 6 kg/chip or more and 7 kg/chip or less, and “Poor” when an applied load of 8 kg/chip or more was needed to remove the joint.

### Presence or Absence of Bleed

In producing an evaluation device, the chip component was not mounted on the substrate after the printing of the solder paste using a metal mask, and the paste was heated at 160° C. for 6 minutes using a reflow device. The cured product of epoxy resin on the substrate was then observed for the presence or absence of bleeds in surface portions, using a microscope. The result is “Good” when a bleed was absent, and “Poor” when a bleed was present.

Insulation against Humidity

The solder paste was printed on a circuit board having a comb-patterned substrate (conductor width=0.3 mm, conductor intervals=0.3 mm), and the space between the electrodes was coated with the resin of the paste. The assembly was then kept in a high-temperature high-humidity vessel (85° C., 85% RH) for 1,000 hours, and a DC voltage of 50 V was applied. The resistance value was measured, and converted into volume resistivity. In the evaluation of insulation against humidity, the result is “Good” when the volume resistivity was 1×10⁸ Ω·cm or more, “Acceptable” when the volume resistivity was 1×10⁷ Ω·cm or more and less than 1×10⁸ Ω·cm, and “Poor” when the volume resistivity was less than 1×10⁷ Ω·cm.

### Overall Evaluation

The overall evaluation result is “Good” when the evaluation results for printability, room-temperature adhesion, high-temperature adhesion, the presence or absence of bleeding, and insulation against humidity were all “Good”. The overall evaluation result is “Acceptable” when any one of these properties was “Acceptable”, and “Poor” when any one of these properties was “Poor”.

In Table 1, the contents are parts by weight.

TABLE 1

| | | | | Ex. 1 | Ex. 2 | Ex. 3 |
|---|---|---|---|---|---|---|
| Formulation | Solder | | Type | SB | SB | SB |
| | | | Weight | 82 | 82 | 80 |
| | | | parts | | | |
| | Flux | Base epoxy resin | Weight | 8.7 | 8.7 | 12.6 |
| | | | parts | | | |
| | | Polybutadiene | Weight | 0.4 | 0.0 | 0.9 |
| | | modified epoxy | parts | | | |
| | | resin | | | | |
| | | Urethane modified | Weight | 0.5 | 0.9 | 0.0 |
| | | epoxy resin | parts | | | |
| | | Reactive diluent | Weight | 3 | 3 | 0 |
| | | EP-4088L | parts | | | |
| | | | phr | 16.7 | 16.7 | 0.0 |
| | | Reactive diluent | Weight | 0 | 0 | 0 |
| | | EP-3950S | parts | | | |
| | | | phr | 0.0 | 0.0 | 0.0 |
| | | Reactive diluent | Weight | 0 | 0 | 1 |
| | | EX-201IM | parts | | | |
| | | | phr | 0.0 | 0.0 | 15 |
| | | Reactive diluent | Weight | 0 | 0 | 0 |
| | | DME100 | parts | | | |
| | | | phr | 0.0 | 0.0 | 0.0 |
| | | Reactive diluent | Weight | 0 | 0 | 0 |
| | | ED-509S | parts | | | |
| | | | phr | 0.0 | 0.0 | 0.0 |
| | | Organic acid | Weight | 3.6 | 3.6 | 3.5 |
| | | (Activating | parts | | | |
| | | agent) | | | | |
| | | Curing agent | Weight | 1.8 | 1.8 | 2.0 |
| | | | parts | | | |
| | Total flux content in parts by weight | | | 18.0 | 18.0 | 20.0 |
| | Total content of epoxy resin in parts | | | 12.6 | 12.6 | 14.5 |
| | by weight | | | | | |
| | Total paste amount in parts by weight | | | 100 | 100 | 100 |
| Fraction | Flux (%) | | | 18 | 18 | 20 |
| | Solder (%) | | | 82 | 82 | 80 |
| Properties | Printability | | | Good | Good | Acceptable |
| | Adhesion | Room temperature | Kg/chip | 15 | 18 | 15 |
| | | | Evaluation | Good | Good | Good |
| | | | result | | | |
| | | 160° C. | Kg/chip | 5 | 7 | 4 |
| | | | Evaluation | Good | Acceptable | Good |
| | | | result | | | |
| | Presence or absence of bleeding | | | Absent | Absent | Absent |
| | Insulation against humidity (in terms | | | Good | Good | Good |
| | of volume resistivity) | | | | | |
| Overall evaluation result | | | | Good | Acceptable | Acceptable |
| | | | | Ex. 4 | Ex. 5 | Ex. 6 |
| Formulation | Solder | | Type | SB | SB | SB |
| | | | Weight | 78 | 82 | 80 |
| | | | parts | | | |
| | Flux | Base epoxy resin | Weight | 8.4 | 9.7 | 10.6 |
| | | | parts | | | |
| | | Polybutadiene | Weight | 0.9 | 0.2 | 0.0 |
| | | modified epoxy | parts | | | |
| | | resin | | | | |
| | | Urethane modified | Weight | 1.0 | 0.7 | 0.9 |
| | | epoxy resin | parts | | | |
| | | Reactive diluent | Weight | 0 | 1 | 3 |
| | | EP-4088L | parts | | | |
| | | | phr | 0.0 | 5.6 | 15.0 |
| | | Reactive diluent | Weight | 6 | 1 | 0 |
| | | EP-3950S | parts | | | |
| | | | phr | 27 | 5.6 | 0.0 |
| | | Reactive diluent | Weight | 0 | 0 | 0 |
| | | EX-201IM | parts | | | |
| | | | phr | 0.0 | 0.0 | 0.0 |
| | | Reactive diluent | Weight | 0 | 0 | 0 |
| | | DME100 | parts | | | |
| | | | phr | 0.0 | 0.0 | 0.0 |
| | | Reactive diluent | Weight | 0 | 0 | 0 |
| | | ED-509S | parts | | | |
| | | | phr | 0.0 | 0.0 | 0.0 |
| | | Organic acid | Weight | 3.4 | 3.6 | 3.5 |
| | | (Activating agent) | parts | | | |
| | | Curing agent | Weight | 2.3 | 1.8 | 2.0 |
| | | | parts | | | |
| | Total flux content in parts by weight | | | 22.0 | 18.0 | 20.0 |
| | Total content of epoxy resin in parts | | | 16.3 | 12.6 | 14.5 |
| | by weight | | | | | |
| | Total paste amount in parts by weight | | | 100 | 100 | 100 |
| Fraction | Flux (%) | | | 22 | 18 | 20 |
| | Solder (%) | | | 78 | 82 | 80 |
| Properties | Printability | | | Good | Good | Good |
| | Adhesion | Room temperature | Kg/chip | 16 | 16 | 18 |
| | | | Evaluation | Good | Good | Good |
| | | | result | | | |
| | | 160° C. | Kg/chip | 2 | 6 | 7 |
| | | | Evaluation | Good | Acceptable | Acceptable |
| | | | result | | | |

| | | | |
|---|---|---|---|
| Presence or absence of bleeding | Absent | Absent | Absent |
| Insulation against humidity (in terms | Good | Good | Good |
| of volume resistivity) | | | |

| | | | |
|---|---|---|---|
| Overall evaluation result | Good | Acceptable | Acceptable |

| | | | | Com. Ex. 1 | Com. Ex. 2 | Com. Ex. 3 | Com. Ex. 4 |
|---|---|---|---|---|---|---|---|
| Formulation | Solder | | Type | SB | SB | SB | SB |
| | | | Weight | 80 | 82 | 80 | 82 |
| | | | parts | | | | |
| | Flux | Base epoxy resin | Weight | 10.6 | 11.7 | 2.5 | 8.7 |
| | | | parts | | | | |
| | | Polybutadiene | Weight | 0.4 | 0.4 | 1.0 | 0.4 |
| | | modified epoxy | parts | | | | |
| | | resin | | | | | |
| | | Urethane modified | Weight | 0.5 | 0.5 | 1.0 | 0.5 |
| | | epoxy resin | parts | | | | |
| | | Reactive diluent | Weight | 0 | 0 | 10 | 0 |
| | | EP-4088L | parts | | | | |
| | | | phr | 0.0 | 0.0 | 50.0 | 0.0 |
| | | Reactive diluent | Weight | 0 | 0 | 0 | 0 |
| | | EP-3950S | parts | | | | |
| | | | phr | 0.0 | 0.0 | 0.0 | 0.0 |
| | | Reactive diluent | Weight | 0 | 0 | 0 | 0 |
| | | EX-201IM | parts | | | | |
| | | | phr | 0.0 | 0.0 | 0.0 | 0.0 |
| | | Reactive diluent | Weight | 3 | 0 | 0 | 0 |
| | | DME100 | parts | | | | |
| | | | phr | 15 | 0.0 | 0.0 | 0.0 |
| | | Reactive diluent | Weight | 0 | 0 | 0 | 3 |
| | | ED-509S | parts | | | | |
| | | | phr | 0.0 | 0.0 | 0.0 | 16.7 |
| | | Organic acid | Weight | 3.5 | 3.6 | 3.5 | 3.6 |
| | | (Activating agent) | parts | | | | |
| | | Curing agent | Weight | 2.0 | 1.8 | 2.0 | 1.8 |
| | | | parts | | | | |
| | Total flux content in parts by weight | | | 20.0 | 18.0 | 20.0 | 18.0 |
| | Total content of epoxy resin in parts | | | 14.5 | 12.6 | 14.5 | 12.6 |
| | by weight | | | | | | |
| | Total paste amount in parts by weight | | | 100 | 100 | 100 | 100 |
| Fraction | Flux (%) | | | 20 | 18 | 20 | 18 |
| | Solder (%) | | | 80 | 82 | 80 | 82 |
| Properties | Printability | | | Good | Poor | Poor | Acceptable |
| | Adhesion | Room temperature | Kg/chip | 16 | 15 | 14 | 13 |
| | | | Evaluation | Good | Good | Poor | Poor |
| | | | result | | | | |
| | | 160° C. | Kg/chip | 5 | 6 | 2 | 3 |
| | | | Evaluation | Good | Acceptable | Good | Good |
| | | | result | | | | |

| | | | | |
|---|---|---|---|---|
| Presence or absence of bleeding | Absent | Present | Absent | Absent |
| Insulation against humidity (in terms | Poor | Good | Acceptable | Acceptable |
| of volume resistivity) | | | | |

| | | | | |
|---|---|---|---|---|
| Overall evaluation result | Poor | Poor | Poor | Poor |

The solder powder used in Example 1 was of the composition 42Sn-58Bi (“SB” in the table) , and was used in 82 weight parts with respect to 100 weight parts of the solder paste. The fraction of the solder was 82 weight % accordingly. The flux contained 0.4 weight parts of polybutadiene modified epoxy resin, and 0.5 weight parts of urethane-modified epoxy resin as rubber modified epoxy resins. The flux also contained 3 weight parts of a reactive diluent EP-4088L (dicyclopentadiene dimethanol diglycidyl ether; ADEKA). This amount translates into 16.7 weight parts (16.7 phr) of the flux weight (a total weight of solder paste components other than the solder powder) taken as 100 weight parts. The flux also contained 3.6 weight parts of organic acid, and 1.8 weight parts of curing agent.

In Example 1, printability was Good because there was no dripping or pointing, and the shape was desirable. The solder paste had a desirable room-temperature adhesion of 15 Kg/chip, and the repairability was desirable with a reduced adhesion of 5 Kg/chip at 160° C. No bleed was observed in the cured product of epoxy resin after reflow. As for insulation against humidity, the volume resistivity was 1×10⁸ Ω·cm or more. Because of these desirable properties, the overall evaluation result was Good.

The solder powder used in Example 2 was of the composition 42Sn-58Bi (“SB” in the table), and was used in 82 weight % in the fraction of the solder with respect to 100 weight parts of the solder paste, as in Example 1. The flux contained 0.9 weight parts of urethane-modified epoxy resin as the sole rubber modified epoxy resin. The flux also contained a base epoxy resin, an organic acid, and a curing agent in the same amounts (weight parts) used in Example 1. The same reactive diluent used in Example 1 was used in the same amount (weight parts).

The solder paste of Example 2 had desirable printability, as in Example 1. The room-temperature adhesion had a desirable value of 18 Kg/chip; however, the solder paste was evaluated as being acceptable for use (Acceptable) because of the slightly high adhesion at 160° C. of 7 Kg/chip. No bleed was observed in the cured product of epoxy resin after reflow. The insulation against humidity was desirable with a volume resistivity of 1×10⁸ Ω·cm or more. The overall evaluation result was Acceptable because the evaluation result for one of the properties was Acceptable. Nonetheless, the properties were overall desirable in the evaluation results for Example 2, making the solder paste sufficient for use.

The solder powders used in Examples 3 to 5 were of the composition 42Sn-58Bi (“SB” in the table). The fraction of the solder is as shown in Table 1. The flux contained the base epoxy resin in the amount (weight parts) shown in the table. The type and the amount (weight parts) of the rubber modified epoxy resin (polybutadiene modified epoxy resin and/or urethane-modified epoxy resin) and the reactive diluent are as shown in the table. The organic acid and the curing agent were also contained, in the amounts (weight parts) shown in the table. The evaluation results for Examples 3 to 5 are presented in Table 1.

The same flux used in Example 1 was used in Example 6. However, the solder powder 42Sn-57Bi-1.0Ag (“SBA” in the table) was used. The evaluation result for Example 6 is presented in Table 1.

In Comparative Example 1, the flux contained 3 weight parts of a reactive diluent DME-100 (1,4-cyclohexane dimethanol diglycidyl ether of the structural formula represented by the chemical formula 6 below; New Japan Chemical Co., Ltd.). The reactive diluent had a viscosity of 50 mPa·s to 100 mPa·s, and a total chlorine content of 5 weight %. This reactive diluent has a not so strong cyclic ring in its skeleton. Accordingly, the cured product of epoxy resin has weak room-temperature adhesion in Comparative Example 1. Because of the very high chlorine ion content, insulation against humidity tends to be poor.

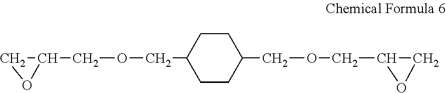 [SMILES: C1CC(COCC2CO2)CCC1COCC1CO1]

In Comparative Example 1, printability was Good because there was no dripping or pointing, and the shape was desirable. Room-temperature adhesion, and adhesion at 160° were also desirable. No bleed was observed in the cured product of epoxy resin after reflow. However, the evaluation result for insulation against humidity was Poor because of the low volume resistivity of 1×10⁶ Ω·cm. This is probably because of the high total chlorine content of 5% in the reactive diluent. From these evaluation results, the solder paste was determined as being unusable (Poor) in the overall evaluation.

In Comparative Example 2, the fraction of the solder was 82 weight %, and the flux did not contain a reactive diluent. In Comparative Example 2, the evaluation result for printability was Poor because of pointing, and a poor print shape. Presumably, this is because of the lack of reactive diluent, leading to high viscosity. A bleed was observed in the cured product of epoxy resin after reflow. This is probably a result of the flux not containing the reactive diluent that acts to improve the compatibility of the rubber modified epoxy resin with the epoxy resin, which has poor compatibility with the rubber modified epoxy resin. From these evaluation results, the solder paste was determined as being unusable (Poor) in the overall evaluation.

In Comparative Example 3, the flux contained 10 weight parts (50 phr) of a reactive diluent EP-4088L (dicyclopentadiene dimethanol diglycidyl ether; ADEKA). In Comparative Example 3, the evaluation result for printability was Poor because of dripping, and a poor print shape. This is probably because of the excess amount of reactive diluent, making the solder paste overly fluidic. The solder paste also had poor room-temperature adhesion, probably because of low crosslink density due to the excess amount of reactive diluent. From these evaluation results, the solder paste was determined as being unusable (Poor) in the overall evaluation.

In Comparative Example 4, the flux contained 3 weight parts of a reactive diluent ED-509S (tert-butylphenyl glycidyl ether of the structural formula represented by the chemical formula 7 below; ADEKA). The reactive diluent had a viscosity of 20 mPa·s, and a total chlorine content of 0.02 weight %.

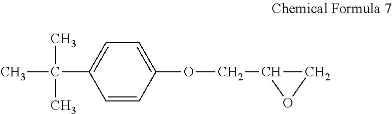

In Comparative Example 4, the evaluation result for printability was Acceptable because the solder paste showed little dripping due to low viscosity and low thixotropy. The solder paste also had a low room-temperature adhesion of 13 Kg/chip. However, the adhesion at 160° C. was very weak, and repairability was desirable. No bleed was observed in the cured product of epoxy resin after reflow. The solder paste had a slightly low volume resistivity of 1×10⁷ Ω·cm, and the evaluation result for insulation against humidity was Acceptable. Presumably, this is because, despite the low total chlorine content of 0.02 weight % in the reactive diluent, the epoxy is monofunctional, and its cured product has low crosslink density, resulting in weak room-temperature adhesion. The weak insulation against humidity is probably because of an increased high moisture absorption rate. From these evaluation results, the solder paste was determined as being unusable (Poor) in the overall evaluation.

From the results shown in Table 1, it was found that a solder paste containing an epoxy resin, a curing agent, an organic acid, a rubber modified epoxy resin, and a solder powder as essential components can exhibit desirable effects (e.g., desirable printability) when the flux contains the predetermined reactive diluent according to the present disclosure. Considering factors such as fluidity, the content of the predetermined reactive diluent is 5 weight % or more and less than 50 weight % (phr) with respect to the total flux weight. The predetermined reactive diluent according to the present disclosure is a low-molecular-weight epoxy resin, and becomes incorporated in the epoxy cross-linked structure upon reaction with the curing agent. Unlike a solvent commonly used for fluxes, the reactive diluent therefore does not turn into a gas and form voids upon being heated.

The compound in the predetermined reactive diluent according to the present disclosure has two or more epoxy groups, and has preferably a skeleton of a rigid structure such as a dicyclopentadiene skeleton, and a benzene ring. Accordingly, a cured product from the solder paste of the embodiment of the present disclosure has high crosslink density, and can desirably develop a solder reinforcing effect while maintaining high room-temperature adhesion. Because the cured product is dense, the moisture absorption rate is low, and a low moisture absorption state can be maintained even when placed under high-temperature high-humidity conditions for extended time periods. The reactive diluent has a very low total chlorine content (an amount of chlorine ions) of 0.5 weight % or less, and the solder paste can maintain a volume resistivity of 1×10⁸ Ω·cm or more even when subjected to a DC voltage of 50 V after 1,000 hours in an 85° C. 85% RH high-temperature high-humidity vessel. With a monofunctional epoxy having a high moisture absorption rate, the volume resistivity was 1×10⁷ Ω·cm or less when the reactive diluent had a high total chlorine content of about 5 weight %.

It was also found in the present disclosure that bleeding, which is believed to be caused by the rubber modified epoxy resin, can be prevented in a cured product of epoxy resin after reflow. The rubber modified epoxy resin containing a polybutadiene skeleton, and the rubber modified epoxy resin containing a polyurethane skeleton have poor compatibility with common epoxys. Accordingly, an unreacted rubber modified epoxy resin bleeds on a surface of the epoxy cured product, and this results in a tacky surface on the cured product, attracting dust and impairing the moisture absorption rate. By appropriately adding the predetermined reactive diluent according to the present disclosure to the solder paste containing these epoxy resins, the compatibility between the epoxy resin and the rubber modified epoxy resin can improve, and bleeding on a surface of the cured product can be prevented, making it possible to improve the practicality of the solder paste.

The solder paste and the mount structure of the embodiment of the present disclosure are applicable to a wide range of applications in the field of techniques for forming electric/electronic circuits. For example, the disclosure is applicable for bonding of electronic components such as CCD devices, hologram devices, and chip components, and for joining of such components to a substrate. The disclosure is therefore also applicable to products in which such devices, components, and substrates are installed, for example, such as DVD devices, cell phones, portable AV devices, and digital cameras.

What is claimed is:

1. A solder paste comprising a solder powder and a flux,
wherein the flux contains an epoxy resin, a reactive diluent, a curing agent, an organic acid, and a rubber modified epoxy resin, the reactive diluent containing a compound with two or more epoxy groups, and having a viscosity of 150 mPa·s or more and 700 mPa·s or less,
the reactive diluent having a total chlorine content of 0.5 weight % or less, and being contained in a proportion of 5 weight % or more and 45 weight % or less with respect to a total weight of the flux.

2. The solder paste according to claim 1, wherein the compound with two or more epoxy groups in the reactive diluent has two or three epoxy groups.

3. The solder paste according to claim 1, wherein the compound with two or more epoxy groups in the reactive diluent includes at least one selected from a group consisting of dicyclopentadiene dimethanol diglycidyl ether, 1,3-bis[(2,3-epoxypropyl)oxy]benzene, and N,N-bis(2,3-epoxypropyl)-4-(2,3-epoxypropoxy)aniline.

4. The solder paste according to claim 1, wherein the reactive diluent is contained in a proportion of 5 weight % or more and 30 weight % or less with respect to the total weight of the flux.

5. The solder paste according to claim 1, wherein the rubber modified epoxy resin includes at least one selected from the group consisting of an epoxy resin having a polybutadiene skeleton, and an epoxy resin having a polyurethane skeleton.

6. The solder paste according to claim 1, wherein the solder powder contains 22 weight % or more and 68 weight % or less of bismuth, 0 weight % or more and 2 weight % or less of silver, 0 weight % or more and 73 weight % or less of indium, and a balance of tin.

7. Amount structure in which an electronic component is mounted on a circuit board with the solder paste of claim 1, the mount structure comprising:
a conductive portion where the electronic component and the circuit board are metallurgically bonded to each other; and
a reinforcing portion formed by a cured product of the flux covering a periphery of the conductive portion.
